(19) United States
(12) Patent Application Publication
(10) Pub. No.: US 2024/0316858 A1
(43) Pub. Date: Sep. 26, 2024

(54) PHOTOINITIATOR PACKAGE (PIP) ENABLING PART PERFORMANCES PRINTED ON LCD BASED TECHNOLOGY

(71) Applicant: BASF SE, Ludwigshafen am Rhein (DE)

(72) Inventors: Emma Louise COURY, Florham Park, NJ (US); Herve DIETSCH, Wyandotte, MI (US)

(21) Appl. No.: 18/572,205

(22) PCT Filed: Jun. 21, 2022
(86) PCT No.: PCT/US2022/034363

§ 371 Date: Dec. 20, 2023

Related U.S. Application Data
(60) Provisional application No. 63/214,060, filed on Jun. 23, 2021.

(51) Int. Cl. B29C 64/129; B29K 33/00; B29K 75/00; B29K 105/00; B33Y 10/00; B33Y 40/20; B33Y 70/10

(52) U.S. Cl. CPC B29C 64/129; B33Y 10/00; B33Y 40/20; B33Y 70/10; B29K 2033/08; B29K 2075/00; B29K 2105/0002; B29K 2105/0005

(57) ABSTRACT

The present disclosure provides photocurable compositions suitable for three-dimensional printing comprising at least one highly crosslinkable acrylate monomer, at least one elastic urethane acrylate oligomer, and a photoinitiator package comprising bis(.cta.5-2,4-cyclopentadien-1-yl)-bis(2,6-difluoro-3-(1H-pyrrol-1-yl)-phenyl) titanium (Irgacure 784), Genomer 7302, and bis-acylphosphine oxide (BAPO).

### BACKGROUND

Three-dimensional (3D) printing generally relies on vat polymerization technology. This technology uses a photosensitive resin cured by a light source in order to produce solid layers. These solid layers eventually produce whole parts. Two types of 3D printers are generally available: digital light processing (DLP) printers and liquid crystal display (LCD) printers. These printers differ in the intensity of their light sources, rely on different wavelengths, and differ in the printing compositions that may be used.

LCD printers are less expensive and able to produce larger parts: however, these printers may provide lower-performance parts. While DLP printers may provide higher quality parts, these printers are considerably more costly.

### BRIEF DESCRIPTION OF THE DRAWINGS

FIG. 1 shows variation in E-modulus according to printer type, exposure time in seconds, and cure time in minutes, for Composition A as described in Example 2.

FIG. 2 shows variation in tensile stress at maximum force according to printer type, exposure time in seconds, and cure time in minutes, for Composition A as described in Example 2.

FIG. 3 shows variation in elongation percentage at break according to printer type, exposure time in seconds, and cure time in minutes, for Composition A as described in Example 2.

FIG. 4 shows variation in impact strength according to printer type, exposure time in seconds, and cure time in minutes, for Composition A as described in Example 2.

FIG. 5 shows variation in E-modulus according to printer type, exposure time in seconds, and cure time in minutes, for Composition B as described in Example 2.

FIG. 6 shows variation in tensile stress at maximum force according to printer type, exposure time in seconds, and cure time in minutes, for Composition B as described in Example 2.

FIG. 7 shows variation in elongation percentage at break according to printer type, exposure time in seconds, and cure time in minutes, for Composition B as described in Example 2.

FIG. 8 shows variation in impact strength according to printer type, exposure time in seconds, and cure time in minutes, for Composition B as described in Example 2.

FIG. 9 shows variation in E-modulus according to printer type, exposure time in seconds, and cure time in minutes, for Composition C as described in Example 2.

FIG. 10 shows variation in tensile stress at maximum force according to printer type, exposure time in seconds, and cure time in minutes, for Composition C as described in Example 2.

FIG. 11 shows variation in elongation percentage at break according to printer type, exposure time in seconds, and cure time in minutes, for Composition C as described in Example 2.

FIG. 12 shows variation in impact strength according to printer type, exposure time in seconds, and cure time in minutes, for Composition C as described in Example 2.

FIG. 13 shows variation in E-modulus according to printer type, exposure time in seconds, and cure time in minutes, for Composition D as described in Example 2.

FIG. 14 shows variation in tensile stress at maximum force according to printer type, exposure time in seconds, and cure time in minutes, for Composition D as described in Example 2.

FIG. 15 shows variation in elongation percentage at break according to printer type, exposure time in seconds, and cure time in minutes, for Composition D as described in Example 2.

FIG. 16 shows variation in impact strength according to printer type, exposure time in seconds, and cure time in minutes, for Composition D as described in Example 2.

FIG. 17 shows variation in E-modulus according to printer type, exposure time in seconds, and cure time in minutes, for Composition E as described in Example 2.

FIG. 18 shows variation in tensile stress at maximum force according to printer type, exposure time in seconds, and cure time in minutes, for Composition E as described in Example 2.

FIG. 19 shows variation in elongation percentage at break according to printer type, exposure time in seconds, and cure time in minutes, for Composition E as described in Example 2.

FIG. 20 shows variation in impact strength according to printer type, exposure time in seconds, and cure time in minutes, for Composition E as described in Example 2.

FIG. 21 shows DLP v. LCD performance for three compositions and resin formulation RF1, described in more detail in Examples below.

FIG. 22 shows DLP v. LCD performance for three compositions and resin formulation RF2, described in more detail in Examples below.

### DETAILED DESCRIPTION

### I. Definitions

Prior to describing the invention in further detail, the terms used in this application are defined as follows unless otherwise indicated.

As used herein, “about” will be understood by persons of ordinary skill in the art and will vary to some extent depending upon the context in which it is used. If there are uses of the term which are not clear to persons of ordinary skill in the art, given the context in which it is used, “about” will mean up to plus or minus 10% of the particular term.

The use of the terms “a” and “an” and “the” and similar referents in the context of describing the elements (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the claims unless otherwise stated. No language in the specification should be construed as indicating any non-claimed element as essential.

“Optional” or “optionally” means that the subsequently described circumstance may or may not occur, so that the description includes instances where the circumstance occurs and instances where it does not.

The term “pre-determined” refers to an element whose identity is known prior to its use.

As used herein, the term “liquid crystal display” or “LCD” refers to a form of 3D printing technology used for creating models, prototypes, patterns, and production of parts in a layer-by-layer fashion using photopolymerization, a process by which light causes chains of molecules to link, forming polymers. Those polymers then make up the body of a three-dimensional solid.

As used herein, the term “Digital Light Processing” or “DLP” refers to an additive manufacturing process, also known as 3D printing and similar to stereolithography, which takes a design created in a 3D modeling software and uses DLP technology to print a 3D object. DLP is a display device based on optical micro-electro-mechanical technology that uses a digital micromirror device. DLP may use a light source in printers to cure resins into solid 3D objects.

Before the present invention is described in greater detail, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Certain ranges are presented herein with numerical values being preceded by the term “about.” The term “about” is used herein to provide literal support for the exact number that it precedes, as well as a number that is near to or approximately the number that the term precedes. In determining whether a number is near to or approximately a specifically recited number, the near or approximating unrecited number may be a number which, in the context in which it is presented, provides the substantial equivalent of the specifically recited number.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

The present disclosure provides photocurable compositions for use in three-dimensional (3D) printing. Specifically, the present disclosure provides photocurable compositions for use in liquid crystal display (LCD) printers. The wavelength and light intensity vary between digital light processing (DLP) printers and LCD printers. Specifically, LCD printers use lower intensity light, which may lead to slower printing and lower conversion. The compositions of the present disclosure enable conversion and provide physical properties analogous to DLP printers on an LCD printer. These compositions comprise three components: a photoinitiator component, a monomer component, and an oligomer component, each of which is discussed in further detail below:

Following are non-limiting aspects of the technology described herein.

In a first aspect is described a photocurable composition comprising: at least one multifunctional acrylate monomer or multifunctional vinyl ether monomer: at least one elastic urethane acrylate oligomer; and at least one photoinitiator, wherein the photoinitiator comprises bis-acylphosphine oxide.

In a second aspect is described the composition of the first aspect, wherein the photoinitiator comprises a mixture of photoinitiators.

In a third aspect is described the composition of the second aspect, wherein the mixture of photoinitiators comprises bis(.eta. 5-2,4-cyclopentadien-1-yl)-bis(2,6-difluoro-3-(1H-pyrrol-1-yl)-phenyl) titanium (Irgacure 784), mercaptan-modified polyether acrylate, and bis-acylphosphine oxide.

In a fourth aspect is described the composition of the third aspect, wherein the mixture of photoinitiators comprises bis(.eta.5-2,4-cyclopentadien-1-yl)-bis(2,6-difluoro-3-(1H-pyrrol-1-yl)-phenyl) titanium (Irgacure 784) in an amount of 0.1 wt. % to 0.6 wt. % as a percentage of the total composition.

In a fifth aspect is described the composition of the third or fourth aspect, wherein the mixture of photoinitiators comprises mercaptan-modified polyether acrylate (Genomer 7302) in an amount of 0.5 wt. % to 1.0 wt. % as a percentage of the total composition.

In a sixth aspect is described the composition of any one of the third through fifth aspects, wherein the mixture of photoinitiators comprises bis-acylphosphine oxide (BAPO) in an amount of 1 wt. % to 5 wt. % as a percentage of the total composition.

In a seventh aspect is described the composition of any one of the first six aspects, wherein the multifunctional acrylate monomer or multifunctional vinyl ether monomer comprises dipropylene glycol diacrylate (DPGDA).

In an eighth aspect is described a method for preparing a three-dimensional article, wherein the method comprises applying successive layers of at least one photocurable composition comprising: at least one multifunctional acrylate monomer or multifunctional vinyl ether monomer: at least one elastic urethane acrylate oligomer; and at least one photoinitiator, wherein the photoinitiator comprises bis-acylphosphine oxide, to fabricate a three-dimensional article.

In a ninth aspect is described the method of the eighth aspect, wherein the successive layers are applied with a liquid crystal display (LCD) printer.

In a tenth aspect is described the method of the eighth aspect, wherein the successive layers of the photocurable composition are exposed to UV irradiation.

In an eleventh aspect is described the method of the tenth aspect, wherein the UV irradiation is at a wavelength of greater than about 405 nm.

In a twelfth aspect is described the method of the tenth or eleventh aspect, wherein the intensity of the UV irradiation is about 1 mW/cm².

In a thirteenth aspect is described the method of any one of the tenth through twelfth aspect, wherein the successive layers of the photocurable composition are exposed to the UV irradiation for a period of time of less than or equal to about 20 seconds, for example between 10 and 20 seconds.

In a fourteenth aspect is described the method of any one of the eighth through thirteenth aspects, further comprising a post-cure step, for example where that post cure step has a post-cure time of up to about 5 min/side, in particular where the post cure step has a post-cure time of about 5 min/side.

### II. Photoinitiator

Photoinitiators may be referred to as functional light absorbers, converting light into radicals to initiate a radical polymerization reaction. The type and amount of the photoinitiator used in the printing process is related to the wavelength and intensity of the light source used by the printer. Effective photoinitiators absorb ultraviolet (UV) light at a wavelength overlapping with the light source.

The photocurable compositions of the present disclosure may be used to print parts with LCD printers. However, as discussed further below; these printers have lower light intensity in comparison to DLP printers. Thus, suitable photoinitiators for compositions used in LCD printers may display high molar absorptivity to permit a lower concentration of photoinitiator to be used in the composition while still allowing for satisfactory curing. The concentration of photoinitiator may impact the quality of the parts printed. Higher concentrations of photoinitiators may lead to shielding of lower layers of the part during curing, resulting in curing gradients. Therefore, a lower concentration of photoinitiator may be preferable.

The compositions of the present disclosure may include one or more photoinitiators. Suitable photoinitiators may include bis(.eta.5-2,4-cyclopentadien-1-yl)-bis(2,6-difluoro-3-(1H-pyrrol-1-yl)-phenyl) titanium (Irgacure 784, available from Ciba Specialty Chemicals). Photoinitiators may be employed alongside additional compounds, such as mercaptan-modified polyether acrylate, sold for example as Genomer 7302 (available from Rahn USA Corp.). Additional suitable photoinitiators include, but are not limited to, bis(2,4,6-trimethylbenzoyl)-phenylphosphine oxide. 2,4,6-trimethylbenzoylphenyl phosphinate, bis(2.δ,-dimethoxy benzoyl)-2,4,4-trimethylpentylphosphine oxide, diphenyl(2,4,6-trimethylbenzoyl)phosphine oxide, alpha-hydroxy cyclohexyl phenyl ketone. 2-hydroxy-1-(4-(4-(2-hydroxy-2-methylpropionyl)benzyl)phenyl-2-methylpropan-1-one. 2-hydroxy-2-methyl-1-phenylpropanone. 2-hydroxy-2-methyl-1-(4-isopropylphenyl)propanone, oligo (2-hydroxy-2-methyl-1-(4-(1-methylvinyl)phenyl)propanone. 2-hydroxy-2-methyl-1-(4-dodecylphenyl)propanone. 2-hydroxy-2-methyl-1-[(2-hydroxyethoxy)phenyl]propanone, benzophenone, substituted benzophenones, and mixtures of any two or more thereof. In any embodiments, the one or more photoinitiators may be diphenyl(2,4,6-trimethylbenzoyl)phosphine oxide, ethyl(2,4,6-trimethylbenzoyl)phenylphosphinate. 1-hydroxycyclohexylphenylketone, and combinations of two or more thereof.

Other suitable photoinitiators include, but are not limited to, bis(2,4,6-trimethylbenzoyl)-phenylphosphine oxide. 2,4,6-trimethylbenzoylphenyl phosphinate, bis(2,6-dimethoxy benzoyl)-2,4,4-trimethylpentylphosphine oxide, diphenyl(2,4,6-trimethylbenzoyl)phosphine oxide, alpha-hydroxy cyclohexyl phenyl ketone. 2-hydroxy-1-(4-(4-(2-hydroxy-2-methylpropionyl)benzyl)phenyl-2-methylpropan-1-one. 2-hydroxy-2-methyl-1-phenylpropanone. 2-hydroxy-2-methyl-1-(4-isopropylphenyl)propanone, oligo (2-hydroxy-2-m ethyl-1-(4-(1-methylvinyl)phenyl)propanone. 2-hydroxy-2-methyl-1-(4-dodecylphenyl)propanone. 2-hydroxy-2-methyl-1-[(2-hydroxyethoxy)phenyl]propanone, benzophenone, substituted benzophenones, and mixtures of any two or more thereof . . .

In a particular embodiment any of the above listed photoinitiators may be used in combination with bis-acyl phosphine oxide (BAPO) or diphenyl-(2,4,6-trimethylbenzoyl)-phosphine oxide (TPO). In particular, the above listed photoinitiators may be used in combination with BAPO. As seen in the examples provided below, the inclusion of BAPO with photoinitiator combinations useful in LCD printers resulted in printed products with stronger physical characteristics, comparable to those utilized in DLP printers.

The photoinitiator or photoinitiators may be present in the composition in an amount of about 0.1 wt. % or greater, about 1.0 wt. % or greater, about 1.5 wt. % or greater, about 2.0 wt. % or greater, about 2.5 wt. % or greater, about 3.0 wt. % or less, about 3.5 wt. % or less, about 4.0 wt. % or less, about 4.5 wt. % or less, about 5.0 wt. % or less, or any value encompassed by these endpoints, as a weight percentage of the total composition.

A mixture of one or more photoinitiators may be used in the compositions of the present disclosure. One such mixture may comprise Irgacure 784, Genomer 7302, and BAPO. In this mixture, Irgacure 784 may be present in an amount of about (0.1 wt. % or greater, about 0.2 wt. % or greater, about 0).3 wt. % or greater, about 0.4 wt. % or less, about 0.5 wt. % or less, about 0.6 wt. % or less, or any value encompassed by these endpoints, as a weight percentage of the total composition. In this mixture, Genomer 7302 may be present in an amount of about 0.50 wt. % or greater, about 0).55 wt. % or greater, about 0.60 wt. % or greater, or about 0.70 wt. % or greater. Genomer 7302 may also be present in an amount of about 0.75 wt. % or less, about 0.80 wt. % or less, about 0).85 wt. % or less, about 0.90 wt. % or less, about 0).95 wt. % or less, about 1.0 wt. % or less, or any value encompassed by these endpoints, as a weight percentage of the total composition. In this mixture, BAPO may be present in an amount of about 1 wt. % or greater, about 2 wt. % or greater, or about 3 wt. % or greater. BAPO may also be present in an amount of about 4 wt. % or less, about 5 wt. % or less, or any value encompassed by these endpoints, as a weight percentage of the total composition. If TPO is used. TPO may be present in an amount of about 1 wt. % or greater, about 2 wt. % or greater, or about 3 wt. % or greater. TPO may also be present in an amount of about 4 wt. % or less, about 5 wt. % or less, or any value encompassed by these endpoints, as a weight percentage of the total composition

### III. Monomer

Provided herein are UV curable compositions (also referred to as photocurable compositions) containing, as a monomer, at least one of a multifunctional acrylate monomer (having more than one acrylate functional group) and a multifunctional vinyl ether monomer (having more than one vinyl functional group), based on the total weight of the composition. Said in another way, the monomer component may include one or more multifunctional acrylate monomers and/or one or more multifunctional vinyl ether monomers. For example, the monomer component may include one or more diacrylate monomers and/or one or more divinyl ether monomers. The monomer component may act at least in part as a reactive diluent.

Suitable ethylenically unsaturated monomers include, but are not limited to. (meth)acrylate monomers. (meth)acrylamide monomers, vinyl monomers, and combinations thereof. For example, suitable (meth)acrylate and (meth)acrylamide monomers include, but are not limited to, isobornyl (meth)acrylate, phenoxyethyl (meth)acrylate, tert-butyl cyclohexyl (meth)acrylate, hexanediol di(meth)acrylate, trimethylolpropane formal (meth)acrylate, polyethylene glycol di(meth)acrylate, isodecyl (meth)acrylate, hexyl (meth)acrylate, cyclohexyl (meth)acrylate. 2-ethylhexyl(meth) acrylate, octyl (meth)acrylate, nonyl (meth)acrylate, stearyl (meth)acrylate. 2-phenoxy (meth)acrylate. 2-methoxyethyl (meth)acrylate, lactone modified esters of acrylic acid, lactone modified esters of methacrylic acid, methacrylamide, methyl (meth)acrylate, butyl (meth)acrylate, isobutyl (meth)acrylate, allyl (meth)acrylate, tetrahydrofuryl (meth)acrylate, n-hexyl (meth)acrylate. 2-(2-ethoxyethoxy)ethyl (meth)acrylate, n-lauryl (meth)acrylate. 2-phenoxyethyl (meth)acrylate, glycidyl (meth)acrylate, glycidyl (meth)acrylate. (meth)acrylated methylamelamines. 2-(N,N-diethylamino)-ethyl (meth)acrylate, neopentyl glycol di(meth)acrylate, alkoxylated neopentyl glycol di(meth)acrylate, ethylene glycol di(meth)acrylate, hexylene glycol di(meth)acrylate, diethylene glycol di(meth)acrylate, tripropylene glycol di(meth)acrylate, tetraethylene glycol di(meth)acrylate, pentaerythritol di(meth)acrylate, pentaerythritol tri(meth)acrylate, pentaerythritol tetra(meth)acrylate, pentaerythritol penta(meth)acrylate, trimethylolpropane tri(meth)acrylate, phenoxyethyl (meth)acrylate, hexanediol di(meth)acrylate. 4-tert-butyl cyclohexyl (meth)acrylate, alkoxylated trimethylolpropane tri(meth)acrylate which contains from 2 to 14 moles of either ethylene or propylene oxide, tri ethylene glycol di(meth)acrylate, tetraethylene glycol di(meth)acrylate, butyl-allyl-ether isobornyl (meth)acrylate, polyethylene glycol di(meth)acrylate, and 4-acryloyl morpholine.

Suitable vinyl monomers include, but are not limited to, N-vinylformamide (NVF), adducts of NVF having diisocyanates such as toluene diisocyanate and isophorone diisocyanate (IPDI), derivatives of N-vinylformamide. N-vinylcaprolactam, N-vinylpyrrolidone, butyl-vinylether. 1,4-butyl-divinylether, dipropyleneglycol-divinylether, triallylisocyanurate, diallylphthalate, and vinyl esters of acetic acid, lauryl acid, dodecanoic acid, cyclohexylcarboxylic acid, adipic acid, glutaric acid and the like.

In an embodiment, the monomer is dipropylene glycol diacrylate (DPGDA).

In another embodiment, the highly crosslinkable monomer is an acrylate monomer selected from the group consisting of a urethane acrylate with functionality of 6, sold for example as Arkema SARTOMER CN968, ethoxylated pentaerythritol tetraacrylate

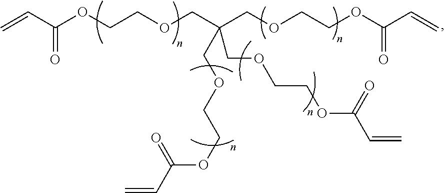

wherein n is 1 or 2, ethoxylated trimethyl propane triacrylate

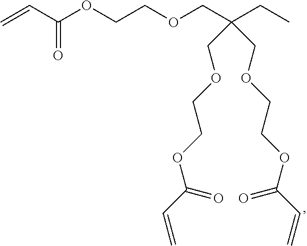 [SMILES: C=CC(=O)OCCOCC(CC)(COCCOC(=O)C=C)COCCOC(=O)C=C]

propoxylated glycerol triacrylate

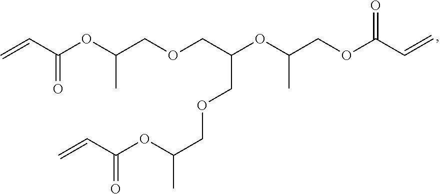 [SMILES: C=CC(=O)OCC(C)OC(COCC(C)OC(=O)C=C)COCC(C)OC(=O)C=C]

trimethylpropane triacrylate

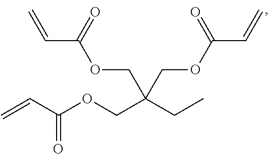 [SMILES: C=CC(=O)OCC(CC)(COC(=O)C=C)COC(=O)C=C]

and dipropylene glycol diacrylate (DPGDA)

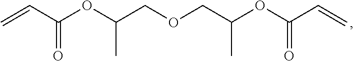 [SMILES: C=CC(=O)OC(C)COCC(C)OC(=O)C=C]

each of which may optionally contain additives to reinforce mechanical and thermal stability, such as silica nanoparticles.

The monomer may be present in the composition in an amount of about 40 wt. % or greater, about 45 wt. % or greater, about 50 wt. % or greater, about 55 wt. % or less, about 60 wt. % or less, or any value encompassed by these endpoints, as a percentage of the total composition.

### IV. Oligomer

In the photopolymerizable 3D printing compositions (also referred to as photocurable compositions) disclosed herein, the monomer is used in combination with an elastic urethane acrylate oligomer. Such oligomers have higher molecular weight flexible chains to offset brittleness and impart elasticity. These oligomers are, for example, long chain diacrylate polyurethane oligomers.

In one embodiment, the urethane acrylate oligomer is a urethane(meth)acrylate of formula (III)

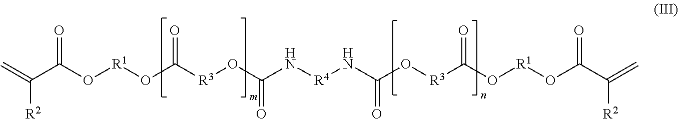

In the above formula, R¹ is a divalent alkylene radical which has 2 to 12 carbon atoms and which may optionally be substituted by C₁ to C₄ alkyl groups, hydroxyl groups, and/or interrupted by one or more oxygen atoms, said radical specifically having 2 to 10 carbon atoms, more specifically 2 to 8, and very specifically having 3 to 6 carbon atoms, R² in each case independently of any other is methyl or hydrogen, specifically hydrogen, R³ is a divalent alkylene radical which has 1 to 12 carbon atoms and which may optionally be substituted by C₁ to C₄ alkyl groups, hydroxyl groups, and/or interrupted by one or more oxygen atoms, said radical having specifically 2 to 10, more specifically 3 to 8, and very specifically 3 to 4 carbon atoms, and n and m independently of one another are positive numbers from 1 to 5, specifically 2 to 5, more specifically 2 to 4, very specifically 2 to 3, and more particularly 2 to 2.5, R⁴ here is a divalent organic radical which is formed by abstraction of both isocyanate groups from an aliphatic, cycloaliphatic or aromatic diisocyanate. Methods of making such urethane acrylate oligomers may be found, for example, in US 2016/0107987, the contents of which are incorporated herein by reference.

Such urethane acrylate oligomers can be made, for example, by reacting hydroxyalkyl(meth)acrylates (A) of the formula

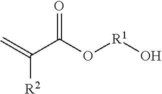

in which R¹ and R² have the definitions set out above with (n+m)/2 equivalents of lactone (B) of formula

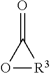

in which R³ has the definitions set out above. This reaction results in an intermediate of formula

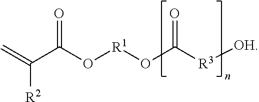

Exemplary hydroxyalkyl(meth)acrylates (A) are selected from 2-hydroxyethyl(meth)acrylate, 2- or 3-hydroxypropyl(meth)acrylate, 1,4-butanediol mono(meth)acrylate, neopentyl glycol mono(meth)acrylate, 1,5-pentanediol mono(meth)acrylate, and 1,6-hexanediol mono(meth)acrylate, very specifically 2-hydroxyethyl(meth)acrylate, 2-hydroxypropyl(meth)acrylate, and 1,4-butanediol mono(meth)acrylate, and especially 2-hydroxyethyl(meth)acrylate. Particular exemplary hydroxyalkyl(meth)acrylates are hydroxyethyl(meth)acrylate, in particular beta-hydroxyethyl acrylate.

Exemplary lactones (B) are selected from beta-propiolactone, gamma-butyrolactone, gamma-ethyl-gamma-butyrolactone, gamma-valerolactone, delta-valerolactone, epsilon-caprolactone, 7-methyloxepan-2-one, 1,4-dioxepan-5-one, oxacyclotridecan-2-one, and 13-butyl-oxacyclotridecan-2-one. A particular exemplary lactone is epsilon-caprolactone.

In a second step, the intermediate formed in the first step is reacted with at least one aliphatic, cycloaliphatic or aromatic diisocyanate to form the urethane acrylate oligomer. Exemplary diisocyanates include dicyclomethane diisocyanate, in particular dicyclohexylmethane-4,4′-diisocyanate. In exemplary urethane acrylate oligomer is obtained by reacting beta-hydroxyethyl acrylate with epsilon-caprolactone, then reacting with dicyclohexylmethane-4,4′-diisocyanate.

In another embodiment, the urethane acrylate oligomer is at least one high strength and high flexibililty urethane(meth)acrylate having a molar mass Mw of 1000 to 5000 g/mol and two ethylenically unsaturated double bonds per molecule, comprising as synthesis components
(a1) at least one aromatic or cycloaliphatic diisocyanate,
(a2) at least one polyesterdiol synthesized from
(a21) optionally a diol having a molar weight below 250 g/mol,
(a22) at least one oligomeric or polymeric diol selected from the group consisting of
(a221) polytetrahydrofurandiol with a molar mass Mn of up to 2900 g/mol and
(a222) at least one polycaprolactonediol with a molar mass Mn of up to 600 g/mol,
(a23) at least one dicarboxylic acid selected from the group consisting of compounds of the formula (Ia)

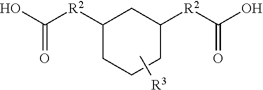

and/or compound of the formula (Ib)

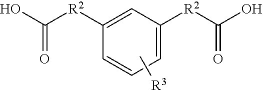

wherein R² is a single bond or a divalent alkylene radical comprising 1 to 3 carbon atoms, and R³ is hydrogen or an alkyl radical comprising 1 to 10 carbon atoms, and (a3) a third compound comprising precisely one isocyanate-reactive group and precisely one free polymerizable group.

Exemplary aromatic diisocyanates include aromatic diisocyanates such as 2,4- or 2,6-tolylene diisocyanate and the isomer mixtures thereof, m- or p-xylylene diisocyanate, 2,4′- or 4,4′-diisocyanatodiphenylmethane and the isomer mixtures thereof, 1,3- or 1,4-phenylene diisocyanate, 1-chloro-2,4-phenylene diisocyanate, 1,5-naphthylene diisocyanate, diphenylene 4,4′-diisocyanate, 4,4′-diisocyanato-3,3′-dimethylbiphenyl, 3-methyldiphenylmethane 4,4′-diisocyanate, tetramethylxylylene diisocyanate, 1,4-diisocyanatobenzene or diphenyl ether 4,4′-diisocyanate.

Exemplary cycloaliphatic diisocyanates include, 4-, 1,3- or 1,2-diisocyanatocyclohexane, 4,4′- or 2,4′-di(isocyanatocyclohexyl)methane, 1-isocyanato-3,3,5-trimethyl-5-(isocyanatomethyl)cyclohexane(isophorone diisocyanate), 1,3- or 1,4-bis(isocyanatomethyl)cyclohexane or 2,4- or 2,6-diisocyanato-1-methylcyclohexane, and also 3 (or 4), 8 (or 9)-bis(isocyanatomethyl)tricyclo[5,2,1,02,6]decane isomer mixtures.

Further exemplary urethane acrylate oligomers are polyurethane acrylates which substantially comprise as components:

(a) at least one organic aliphatic, aromatic or cycloaliphatic di- or polyisocyanate, (b) at least one compound having at least one group reactive toward isocyanate and at least one unsaturated group capable of free radical polymerization and (c) optionally at least one compound having at least two groups reactive toward isocyanate.

Aliphatic, aromatic, and cycloaliphatic di- and polyisocyanates have an NCO functionality of at least 1.8, optionally from 1.8 to 5, and particularly optionally from 2 to 4, and isocyanurates, biurets, allophanates, and uretdiones thereof are suitable as component (a).

Components (b) may be, for example, monoesters of α,β-unsaturated carboxylic acids, such as acrylic acid, methacrylic acid, crotonic acid, itaconic acid, fumaric acid, maleic acid, acrylamidoglycolic acid or methacrylamidoglycolic acid, or vinyl ethers with di- or polyols, which preferably have 2 to 20 carbon atoms and at least two hydroxyl groups, such as ethylene glycol, diethylene glycol, triethylene glycol, 1,2-propylene glycol, 1,3-propylene glycol, 1,1-dimethyl-1,2-ethanediol, dipropylene glycol, triethylene glycol, tetraethylene glycol, pentaethylene glycol, tripropylene glycol, 1,4-butanediol, 1,5-pentanediol, neopentylglycol, 1,6-hexanediol, 2-methyl-1,5-pentanediol, 2-ethyl-1,4-butanediol, 1,4-dimethylolcyclohexane, 2,2-bis(4-hydroxy cyclohexyl)propane, glycerol, trimethylolethane, trimethylolpropane, trimethylolbutane, pentaerythritol, ditrimethylolpropane, erythritol, sorbitol, poly-THF having a molecular weight of from 162 to 2900, poly-1,3-propanediol having a molecular weight of from 134 to 400 or polyethylene glycol having a molecular weight of from 238 to 458. It is furthermore possible to use esters or amides of (meth)acrylic acid with amino alcohols, e.g. 2-aminoethanol, 2-(methylamino)ethanol, 3-amino-1-propanol, 1-amino-2-propanol or 2-(2-aminoethoxy)ethanol, 2-mercaptoethanol or polyaminoalkanes, such as ethylenediamine or diethylenetriamine, or vinylacetic acid.

Compounds which are suitable as component (c) are those which have at least two groups reactive toward isocyanate, for example —OH, —SH, —NH₂ or —NHR₂, where R² therein, independently of one another, may be hydrogen, methyl, ethyl, isopropyl, n-propyl, n-butyl, isobutyl, sec-butyl or tert-butyl.

These are preferably diols or polyols, such as hydrocarbondiols having 2 to 20 carbon atoms. e.g. ethylene glycol, 1,2-propanediol, 1,3-propanediol, 1,1-dimethylethane-1,2-diol, 1,6-hexanediol, 1,10-decanediol, bis-(4-hydroxycyclohexane)isopropylidene, tetramethylcyclobutanediol, 1,2-, 1,3- or 1,4-cyclohexanediol, cyclooctanediol, norbornanediol, pinanediol, decalindiol, etc., esters thereof with short-chain dicarboxylic acids, such as adipic acid or cyclohexanedicarboxylic acid, carbonates thereof, prepared by reaction of the diols with phosgene or by transesterification with dialkyl or diaryl carbonates, or aliphatic diamines, such as methylene- and isopropylidenebis(cyclohexylamine), piperazine, 1,2-, 1,3- or 1,4-diaminocyclohexane, 1,2-, 1,3- or 1,4-cyclohexanebis(methylamine), etc., dithiols or polyfunctional alcohols, secondary or primary amino alcohols, such as ethanolamine, diethanolamine, monopropanolamine, dipropanolamine, etc., or thioalcohols, such as thioethylene glycol.

The at least one oligomer may be present in the composition in an amount of about 40) wt. % or greater, about 45 wt. % or greater, or about 50 wt. % or greater. The at least one oligomer may also be present in an amount of about 55 wt. % or less, about 60 wt. % or less, or any value encompassed by these endpoints, as a percentage of the total composition.

In another aspect of the present disclosure, the composition contains the one or more highly crosslinkable monomers and the at least one elastic urethane acrylate oligomer in a weight ratio of about 20:80 to 80:20, for example 30:70 to 70:30, for example 60:40 to 40:60.

### V. Additives

In another aspect of the present disclosure, in addition to the above mentioned highly crosslinkable monomers and elastic oligomers, the composition may have one or more dyes, pigments, or coloring agents. For example, such dyes, pigments, or coloring agents may be used to provide color or to avoid potential discoloration during printing and/or aging of the printed parts. Exemplary dyes, pigments, or coloring agents include carbon black pigment, white pigment and a variety of dyes like cyan, magenta, yellow etc. In particular, the composition includes carbon black, for example in an amount of from 0.005 to 0.1% by weight, for example 0.01 to 0.1% by weight, in particular 0.01 to 0.05% by weight, based on the total weight of the composition. In compositions containing pigments, use may be made of one or more dispersants. Such dispersants would be known to an ordinary skilled artisan. For example, it may be possible to use EFKA4701. Dispersants may be used in an amount of around 10 to 100 ppm for example 20 to 50 ppm, in particular 20 ppm based on the weight of the total composition.

### VI. Printed Parts

Printed parts, such as three-dimensional (3D) articles, may be produced by applying successive layers of one the compositions of the present disclosure. These layers may then be irradiated with UV irradiation to cure the printed part. While both LCD and DLP printers may be used to create printed parts, the two differ in the light sources they use. DLP printers use ultraviolet (UV) light sources. These light sources may have wavelengths in the region of about 385 nm. Generally, the intensity of the light source is between 4 mW/cm² and 9 mW/cm², for example between 5 mW/cm² and 9 mW/cm². In contrast, LCD printers use LED light, with wavelengths higher than about about 400 nm, for example higher than about 405 nm, in particular 440 nm or higher. The intensity of the light source is much lower than that of DLP printers, being generally around 1 mW/cm² in LCD printers. As such, using different printers requires the use of different photoinitiators, as discussed above.

The physical properties of printed parts may vary considerably depending upon the type of printer used to create them. LCD printers are capable of printing larger parts: however, parts created on an LCD printer tend to display less desirable mechanical properties, such as impact strength, percent elongation, elastic modulus (E-modulus) and tensile strength. Furthermore, LCD printers generally display lower conversion. DLP printers create parts with improved mechanical properties: however, these printers are more expensive and therefore possibly less attractive to consumers.

Exposure time and post cure time may also have an effect on the printed part. As described further below; simply using a composition intended for a DLP printer in an LCD printer results in parts with poor mechanical properties. Specifically, these parts demonstrate lower tensile strength and lower E-modulus than those created on a DLP printer. However, increasing both exposure time and post cure time, as well as changing photoiniator package, results in parts printed on an LCD printer that display tensile strength and E-modulus similar to those printed on a DLP printer.

The present disclosure adapts compositions normally used on DLP printers for use in LCD printers. As discussed above, changing the photoinitiator package may permit a composition nominally intended for use in a DLP printer to be successfully used in an LCD printer. Surprisingly, these adapted compositions provide parts from LCD printers with mechanical properties similar to those from DLP printers, as shown in further detail below. Adapting the composition for use in an LCD printer also provides for larger parts to be created than would be possible on a DLP printer. As an example, LCD printers may have a build volume of up to about 510×280×350 mm, while DLP printers may have build volumes for example of about 192×108×350 mm.

### EXAMPLES

In the examples that follow, two different resin formulations were used in the testing being detailed. In the first, a urethane acrylate oligomer (Laromer UA 9089) was used in a 60/40 weight ratio with DPGDA (RF1). In the second, a different urethane acrylate oligomer (Laromer LR 8986) was used in a 75/25 weight ratio with DPGDA (RF2).

### Example 1: Physical Properties of Aromatic Epoxy Acrylate Photopolymer

Compositions A through E were formulated utilizing resin formulation RF2. Composition A included Irgacure 784 in an amount of 0.5 wt. % and Genomer 7302 in an amount of 0).75 wt. %, each as a percentage of the total composition. Composition B included Irgacure 784 in an amount of 1 wt. % and Genomer 7302 in an amount of 0).75 wt. % as percentages of the total composition, respectively. Composition C included Irgacure 784 in an amount of 0).5 wt. %, Genomer 7302 in an amount of 0).75 wt. %, and diphenyl-(2,4,6-trimethylbenzoyl)-phosphine oxide (TPO) in an amount of 4 wt. %, each as percentages of the total composition. Composition D included BAPO in an amount of 3 wt. % as a percentage of the total composition. Finally, Composition E included Irgacure 784 in an amount of 0.5 wt. %, Genomer 7302 in an amount of 0.75 wt. %, and BAPO in an amount of 3 wt. %, each as a percentage of the total composition. The parts were then tested for comparison to parts printed on a DLP printer. The results of these tests are shown below in Table 1.

TABLE 1

| Composition | Result (compared to DLP) |
|---|---|
| A | Lower E-modulus |
| | Lower tensile strength |
| | Higher elongation |
| B | Yet lower E-modulus |
| | Yet lower tensile strength |
| C | Increased E-modulus |
| | Increased tensile strength; concern about excess TPO |
| | leaching out of product |
| D | Similar to C, but with reduced print quality |
| E | Similar to C, with very good print quality. Further, no |
| | concern with leaching out of TPO |

In addition to the results shown above, it was noted that parts printed with Composition A appeared to be undercured. Thus, the amount of the Irgacure 784 photoinitiator was increased in Composition B in an attempt to overcome this issue. However, parts printed with the higher amount of photoinitiator used in Composition B resulted in parts that were tacky, which suggested that post cure improvements were needed. To affect this improvement, TPO was added to create Composition C, which demonstrated a significant increase in both E-modulus and tensile strength in comparison to Composition B. However, there was concern that excess, unreacted TPO may have migrated, and thus resulted in a buildup of unreacted TPO on the surface. To overcome this issue, BAPO was used as the sole photoinitiator in Composition D. Although parts printed using this composition were mechanically similar to those printed using Composition C, the observed print quality was poor. Thus, Composition E included a mixture of Irgacure 784, Gemoner 7302, and BAPO. Parts printed using this composition again displayed mechanical properties similar to those printed using Composition C, but print quality was improved over Composition D.

### Example 2: Effect of Exposure Time and Post Cure Time on Physical Properties

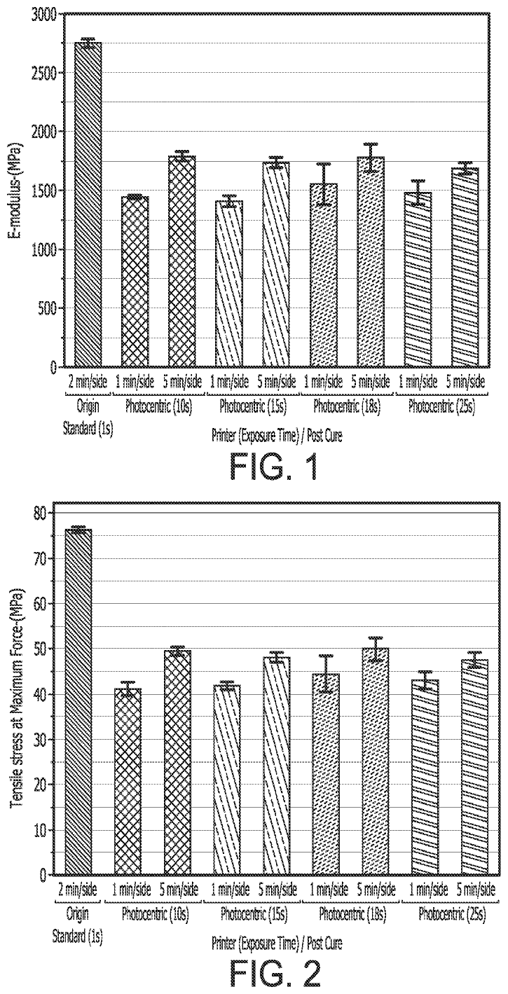

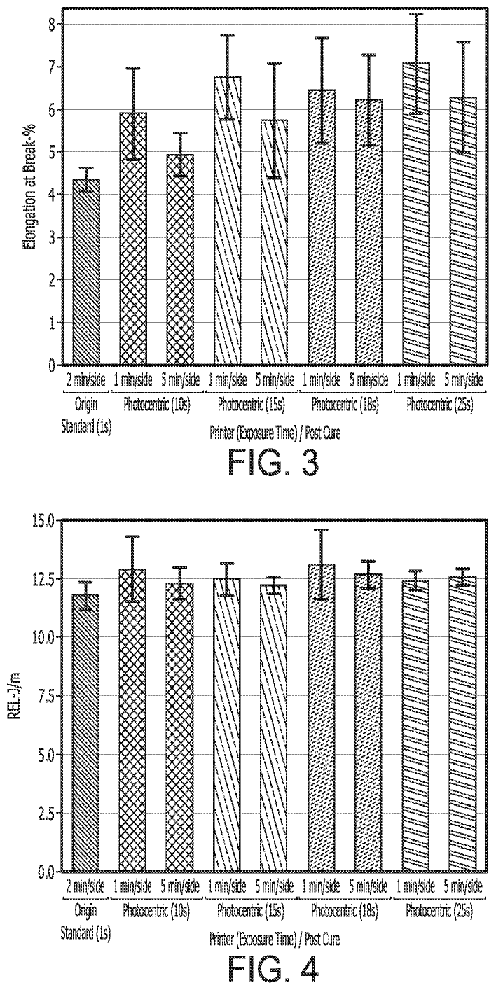

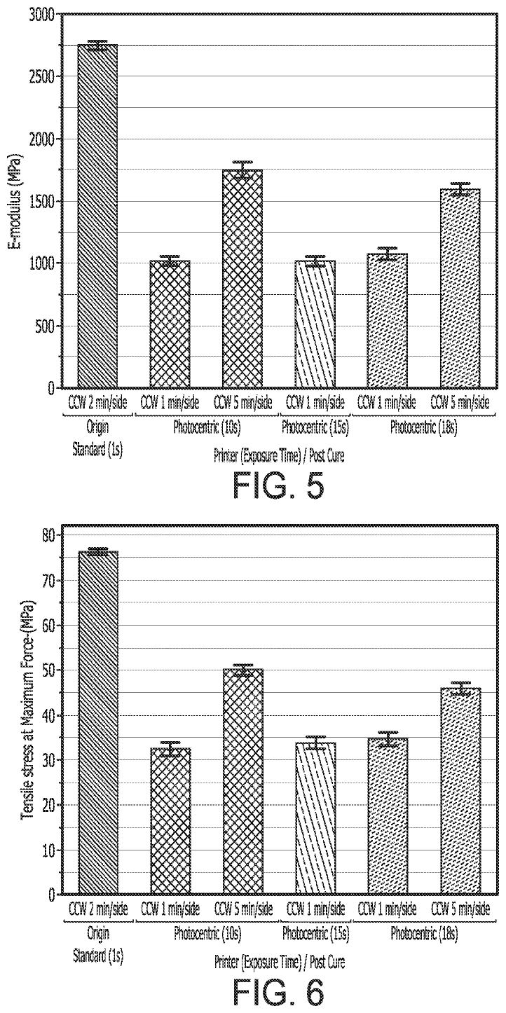

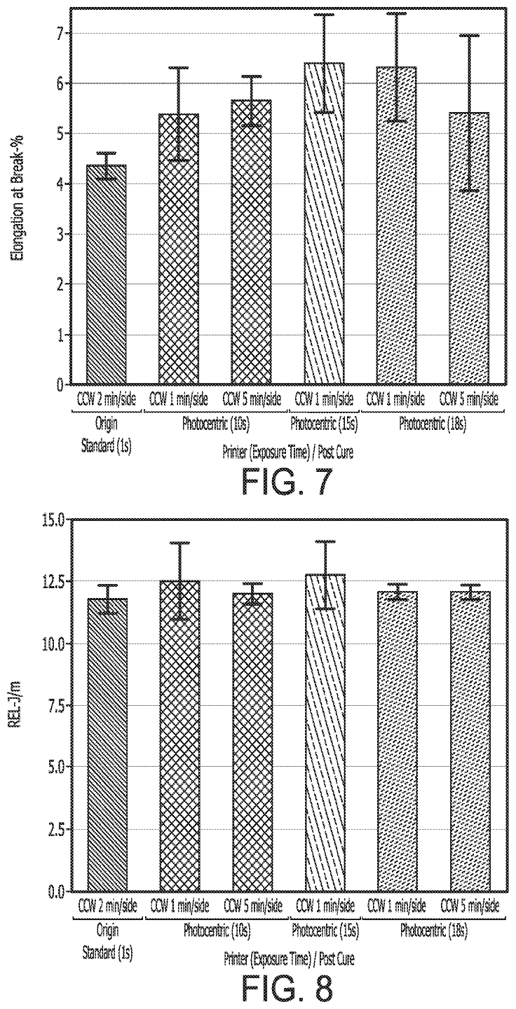

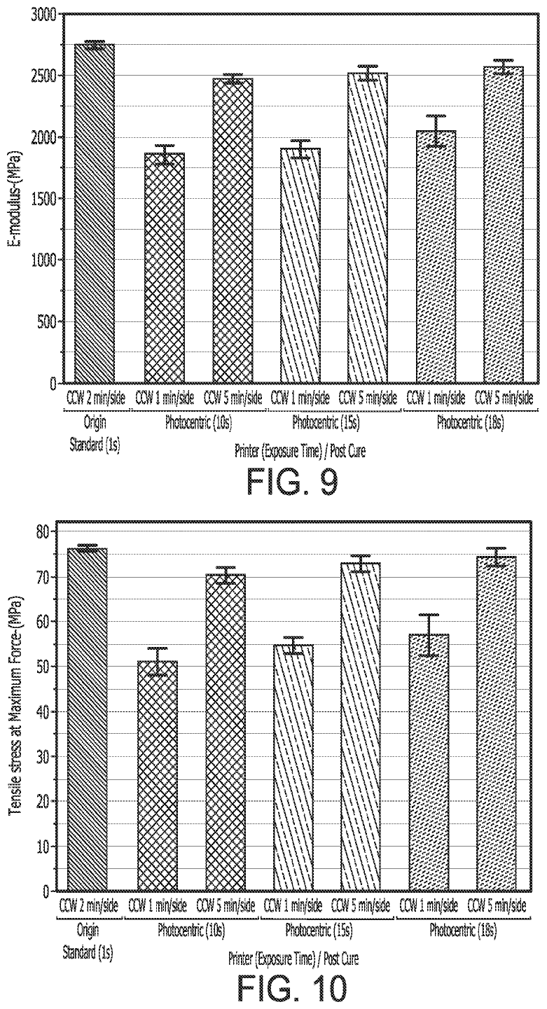

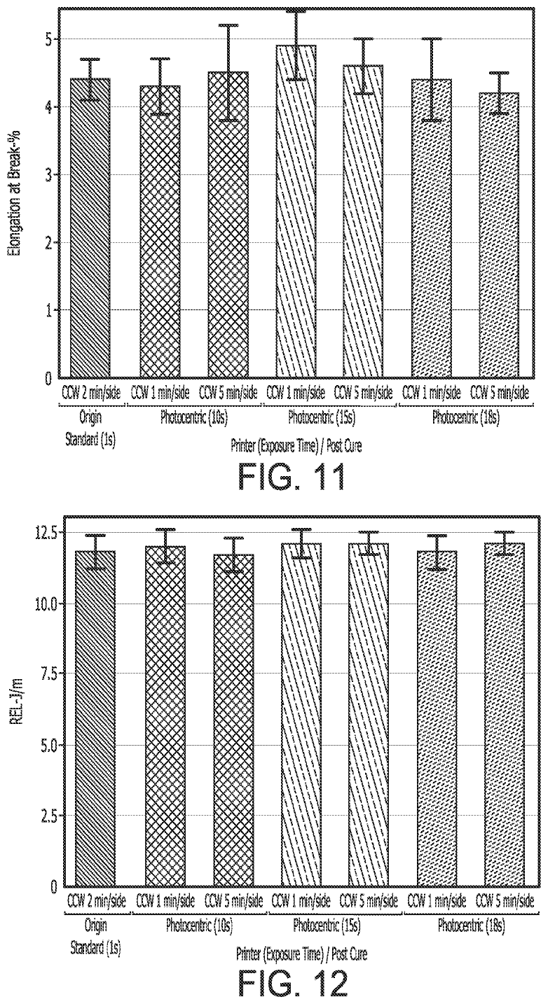

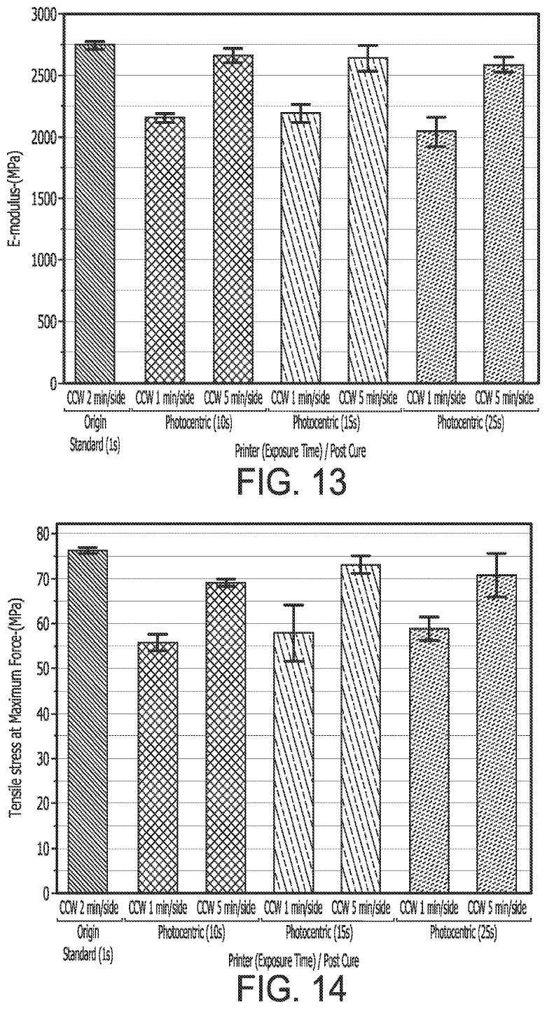

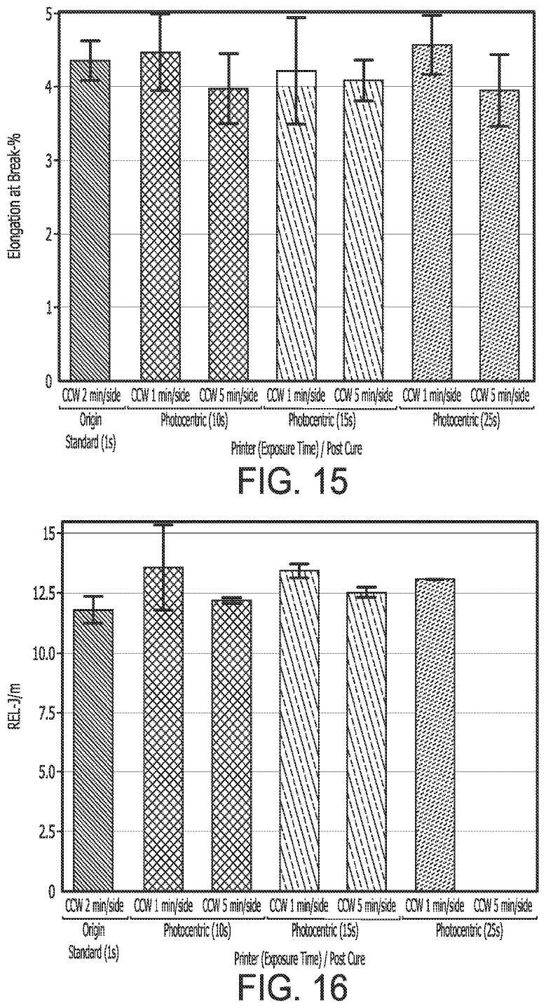

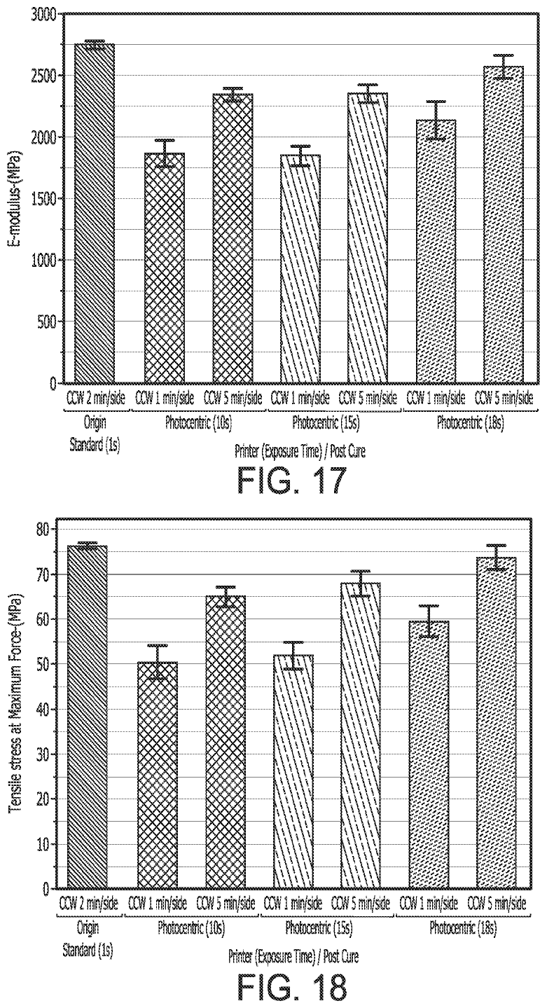

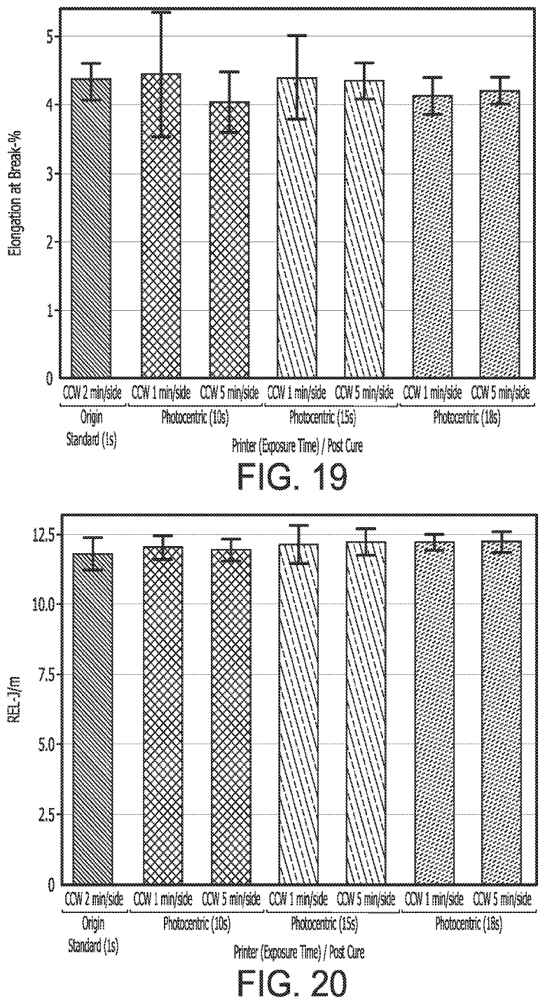

Using both a DLP and an LCD printer, parts were printed using each of the above compositions and resin formulation RF2 from Example 1. Post cure was completed in a 405 nm UV chamber. Both exposure time and post cure time were varied, and E-modulus, tensile strength, elongation at break, and impact strength of the parts were tested. These results are shown graphically in FIGS. 1-20. As shown therein, the improvement of properties noted in Example 1 above were maintained consistently, with the greatest improvement in E-modulus and tensile strength when using 18 s exposure time and 5 min/side post cure time. Elongation was not as affected by exposure time or post cure time.

### Example 3: Physical Properties of Urethane Photopolymers

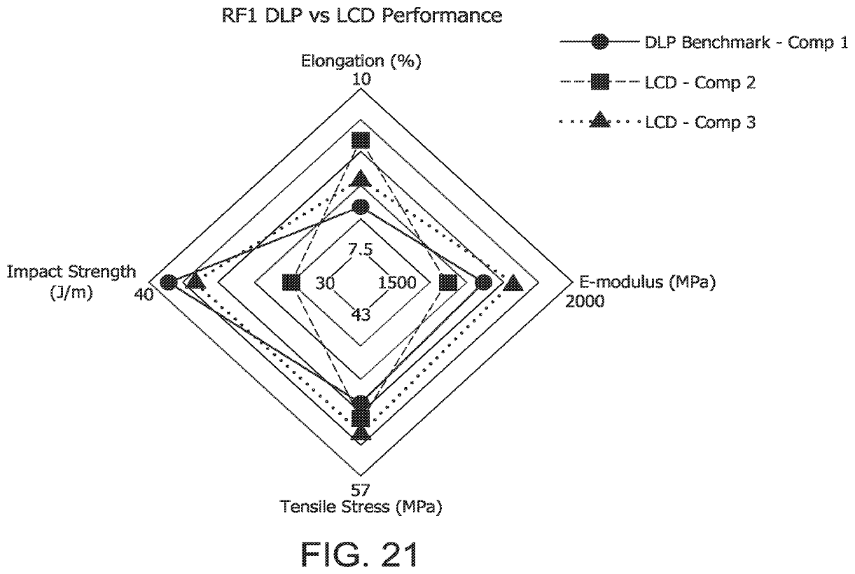

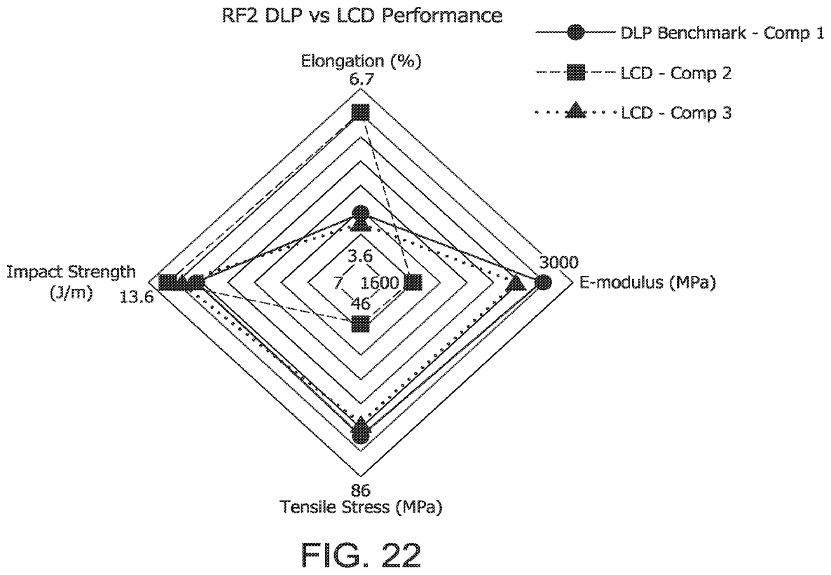

A reactive urethane photopolymer was formulated with three different photoinitiator packages and used for printing parts on two different printers. Composition 1 included Irgacure TPO in an amount of 1 wt. % of the total composition. This composition was used to print parts on a DLP printer. Composition 2 included Irgacure 784 in an amount of 0.5 wt. % and Genomer 7302 in an amount of 0.75 wt. % as percentages of the total composition, respectively. This composition was used to print parts on an LCD printer. Composition 3 included Irgacure 784 in an amount of 0.5 wt. %, Genomer 7302 in an amount of 0.75 wt. %, and BAPO in an amount of 3 wt. %, each as percentages of the total composition. The parts were then tested for impact strength, percent elongation, elastic modulus (E-modulus) and tensile strength. Percent elongation, tensile strength, and E-modulus were calculated according to ASTM D638. Impact strength (notched) was calculated according to ASTM D256. The results of these tests are shown below in FIGS. 21 and 22. In FIG. 21, resin formulation RF1 was utilized. In FIG. 22, resin formulation RF2 was utilized.

As shown in those figures, although printed on an LCD printer, Composition 3 provided parts possessing comparable mechanical properties to those parts printed on a DLP printer using Composition 1.

### Example 4: Effect of Curing Time on Physical Properties

The same reactive urethane photopolymer and compositions described in Example 3 were used to test the effects of different exposure and post-cure times on the mechanical properties of printed parts utilizing resin formulation RF1. The results are shown below in Table 2.

TABLE 2

| Printer | DLP | LCD | LCD | LCD | LCD | LCD | LCD | LCD |
|---|---|---|---|---|---|---|---|---|
| Composition | 1 | 2 | 3 | | | | | |
| Exposure Time (s) | 2 | 15 | 10 | | 15 | | 18 | |
| Post-Cure | 2 | 1 | 1 | 5 | 1 | 5 | 1 | 5 |
| Time | | | | | | | | |
| (min/side) | | | | | | | | |
| Tensile | 51 ± 1 | 52 ± 1 | 45 ± 1 | 51 ± 1 | 50 ± 2 | 53 ± 2 | 50 ± 2 | 51 ± 1 |
| Strength | | | | | | | | |
| E-Modulus | 1745 ± 21 | 1643 ± 27 | 1527 ± 40 | 1724 ± 23 | 1725 ± 59 | 1828 ± 44 | 1701 ± 51 | 1735 ± 40 |
| (MPa) | | | | | | | | |
| Elongation | 8.2 ± 1.6 | 9.2 ± 1.9 | 11.0 ± 1.5 | 9.6 ± 1.0 | 9.5 ± 1.7 | 8.6 ± 3.1 | 9.0 ± 1.7 | 9.2 ± 1.3 |
| (%) | | | | | | | | |
| Impact | 39 ± 8 | 32 ± 6 | 51 ± 10 | 51 ± 8 | 41 ± 9 | 38 ± 7 | 47 ± 7 | 48 ± 6 |
| Strength (J/m) | | | | | | | | |

Again, the mechanical properties demonstrated by the parts printed on an LCD printer using Composition 3 were generally comparable to the results using Composition 1 on a DLP printer.

### Example 5: Effect of Layer Thickness on Physical Properties

Parts were printed using DLP and LCD printers, and their physical properties were compared. The results are shown below in Table 3. The composition utilized for LCD prints contained 0.5 wt % Irgacure 784, 0.75% Genomer 7302 (Composition 2 above), in combination with resin formulation RF1. Composition 1 was used for DLP printing.

TABLE 3

| Printer | DLP | LCD | LCD | LCD |
|---|---|---|---|---|
| Print Parameters | 2 s, 100 um | 5.5 s, 25 um | 6.5 s, 50 um | 15 s, 100 um |
| Tensile Strength (MPa) | 51 ± 1 | 52 ± 1 | 50 ± 0 | 52 ± 1 |
| E-Modulus (MPa) | 1745 ± 21 | 1655 ± 39 | 1535 ± 38 | 1643 ± 27 |
| Elongation (%) | 8.2 ± 1.6 | 8.5 ± 2.3 | 12.1 ± 2.8 | 9.2 ± 1.9 |
| Impact Strength (J/m) | 39 ± 8 | 33 ± 5 | 39 ± 6 | 32 ± 6 |

As seen above, parts printed on an LCD printer using 100 um layer thickness most closely approach the DLP benchmark in mechanical properties. This thickness would also save time during printing, resulting in cheaper fabrication due to increased layer thickness.

### Example 5: Effect of Amount of BAPO on Physical Properties

Nine formulations were prepared using a reactive urethane photopolymer with photoinitiator packages including Irgacure 784 in an amount of 0.5 wt. % and Genomer 7302 in an amount of 0.75 wt. %, each as a percentage of the total formulation. In each formulation, the amount of BAPO was varied, as shown in Table 5 below. Each of the nine formulations were used to print parts on an LCD printer, with an exposure time of 15 seconds and a post cure time of 5 minutes/side at 405 nm. These parts were compared to those printed on a DLP printer using the same reactive urethane photopolymer and a photoinitiator package comprising diphenyl-(2,4,6-trimethylbenzoyl)-phosphine oxide (TPO) in an amount of 1 wt. % as a percentage of the total formulation. The exposure time was 2 seconds and the post cure time was 2 minutes/side at 405 nm.

The parts printed with each formulation were then tested for elongation at break, E-modulus, tensile stress at maximum force, and resistance to deformation on impact (REL, impact strength). The results are shown in Table 4, utilizing resin formulation RF1.

TABLE 4

| | Wt. % | Elongation | E-modulus | Tensile Stress | REL |
|---|---|---|---|---|---|
| Printer | BAPO | (%) | (MPa) | (MPa) | (J/m) |
| LCD | 0 | 9.5 ± 1.5 | 1793 ± 28 | 51.9 ± 1.0 | 33.5 ± 5.3 |
| LCD | 0.5 | 6.5 ± 2.0 | 1873 ± 45 | 54.5 ± 0.7 | 28.6 ± 2.2 |
| LCD | 1 | 7.8 ± 1.6 | 1881 ± 42 | 54.6 ± 0.7 | 31.2 ± 3.6 |
| LCD | 2 | 9.5 ± 3.0 | 1870 ± 37 | 54.2 ± 0.9 | 30.0 ± 3.2 |
| LCD | 3 | 8.6 ± 3.1 | 1828 ± 44 | 53.2 ± 1.5 | 37.5 ± 7.2 |
| LCD | 4 | 8.4 ± 1.7 | 1807 ± 41 | 52.9 ± 0.9 | 40.9 ± 8.8 |
| LCD | 5 | 10.0 ± 1.7 | 1740 ± 56 | 50.6 ± 1.0 | 41.5 ± 4.1 |
| LCD | 6 | 8.6 ± 0.9 | 1724 ± 80 | 50.8 ± 2.2 | 50.0 ± 4.2 |
| LCD | 7 | 7.3 ± 1.1 | 1735 ± 25 | 50.9 ± 0.7 | 50.9 ± 5.0 |
| DLP | — | 8.2 ± 1.6 | 1745 ± 21 | 50.7 ± 0.5 | 38.9 ± 7.6 |

Preferred embodiments of this invention are described herein, including the best mode known to the inventors for carrying out the invention. It will be appreciated that the invention is not restricted to the details described above with reference to the preferred embodiments but that numerous modifications and variations can be made without departing from the spirit and scope of the invention as defined by the following claims.

1.-14. (canceled)

15. A photocurable composition comprising:
at least one multifunctional acrylate monomer or multifunctional vinyl ether monomer;
at least one elastic urethane acrylate oligomer; and
at least one photoinitiator, wherein the photoinitiator comprises bis-acylphosphine oxide.

16. The composition of claim 15, wherein the photoinitiator comprises a mixture of photoinitiators.

17. The composition of claim 16, wherein the mixture of photoinitiators comprises bis(eta5-2,4-cyclopentadien-1-yl)-bis(2,6-difluoro-3-(1H-pyrrol-1-yl)-phenyl) titanium, mercaptan-modified polyether acrylate, and bis-acylphosphine oxide.

18. The composition of claim 17, wherein the mixture of photoinitiators comprises bis(eta5-2,4-cyclopentadien-1-yl)-bis(2,6-difluoro-3-(1H-pyrrol-1-yl)-phenyl) titanium in an amount of 0.1 wt. % to 0.6 wt. % as a percentage of the total composition.

19. The composition of claim 17, wherein the mixture of photoinitiators comprises mercaptan-modified polyether acrylate in an amount of 0.5 wt. % to 1.0 wt. % as a percentage of the total composition.

20. The composition of claim 17, wherein the mixture of photoinitiators comprises bis-acylphosphine oxide (BAPO) in an amount of 1 wt. % to 5 wt. % as a percentage of the total composition.

21. The composition of claim 15, wherein the multifunctional acrylate monomer or multifunctional vinyl ether monomer comprises dipropylene glycol diacrylate (DPGDA).

22. A method of preparing a three-dimensional article, wherein the method comprises applying successive layers of one a photocurable composition comprising:
at least one multifunctional acrylate monomer or multifunctional vinyl ether monomer;
at least one elastic urethane acrylate oligomer; and
at least one photoinitiator, wherein the photoinitiator comprises bis-acylphosphine oxide to fabricate a three-dimensional article.

23. The method of claim 22, wherein the successive layers are applied with a liquid crystal display (LCD) printer.

24. The method of claim 22, wherein the successive layers of the photocurable composition are exposed to UV irradiation.

25. The method of claim 24, wherein the UV irradiation is at a wavelength of greater than about 405 nm.

26. The method of claim 24, wherein the intensity of the UV irradiation is about 1 mW/cm².

27. The method of claim 24, wherein the successive layers of the photocurable composition are exposed to the UV irradiation for a period of time of less than or equal to 20 seconds.

28. The method of claim 22, further comprising a post-cure time of up to about 5 min/side.
